(19) United States
(12) Patent Application Publication
(10) Pub. No.: US 2014/0251659 A1
(43) Pub. Date: Sep. 11, 2014

(54) CIRCUIT BOARD, AND MANUFACTURING METHOD FOR CIRCUIT BOARD

(71) Applicants: Hiroaki Asano, Kariya-shi (JP); Yasuhiro Koike, Kariya-shi (JP); Kiminori Ozaki, Kariya-shi (JP); Hitoshi Shimadu, Kariya-shi (JP); Tetsuya Furuta, Kariya-shi (JP); Masao Miyake, Kariya-shi (JP); Takahiro Hayakawa, Ogaki-shi (JP); Tomoaki Asai, Nagoya-shi (JP); Ryou Yamauchi, Hashima-shi (JP)

(72) Inventors: Hiroaki Asano, Kariya-shi (JP); Yasuhiro Koike, Kariya-shi (JP); Kiminori Ozaki, Kariya-shi (JP); Hitoshi Shimadu, Kariya-shi (JP); Tetsuya Furuta, Kariya-shi (JP); Masao Miyake, Kariya-shi (JP); Takahiro Hayakawa, Ogaki-shi (JP); Tomoaki Asai, Nagoya-shi (JP); Ryou Yamauchi, Hashima-shi (JP)

(73) Assignee: KABUSHIKI KAISHA TOYOTA JIDOSHOKKI, Aichi-ken (JP)

(21) Appl. No.: 14/129,408

(22) PCT Filed: Jul. 2, 2012
(86) PCT No.: PCT/JP2012/066900

§ 371 Date: Feb. 4, 2014

(30) Foreign Application Priority Data
Jul. 6, 2011 (JP) 2011-150265

(51) Int. Cl. H05K 1/11; H05K 3/30; H05K 1/09; H05K 3/00; H05K 1/02; H05K 1/18

(52) U.S. Cl. CPC H05K 1/115; H05K 1/0272; H05K 1/0201; H05K 1/185; H05K 1/09; H05K 3/0058; H05K 3/30
USPC 174/252; 174/268; 174/262; 174/264; 174/260; 174/257; 29/832

(57) ABSTRACT

A circuit board, onto which an electronic component is to be mounted, is provided with insulating core substrates and patterned metal plates. The metal plates are bonded to at least one side of the insulating core substrates. The insulating core substrates and the metal plates form a laminated body, in which a gas-vent hole is provided. The gas-vent hole is formed so that when the electronic component is mounted, the gas present between the insulating core substrates and the metal plates expands and is released to a side open to the atmosphere via the gas-vent hole.

### TECHNICAL FIELD

The present invention relates to a circuit board and a method for manufacturing the circuit board.

### BACKGROUND ART

Patent Document 1 discloses a method for manufacturing a metal-based multilayered circuit board. The method includes a step of forming a conductor circuit on a metal plate with an insulating adhesive layer in between and a step of bonding a circuit conductor layer to the conductor circuit with a second insulating adhesive layer in between.

### PRIOR ART DOCUMENT

### Patent Document

### Patent Document 1: Japanese Laid-Open Patent Publication No. 9-139580

### SUMMARY OF THE INVENTION

### Problems that the Invention is to Solve

In some cases, a pattern forming copper plate may be bonded to an insulating core substrate before components are reflow-soldered to the pattern forming copper plate. In such a case, a gap, which is a void, may be formed between the copper plate and the insulating core substrate as a gap resulting from insufficient adhesion between the copper plate and the insulating core substrate. The gap expands and increases in volume as the gas in the gap expands at the time of reflow mounting of components, or, in other words, in a high temperature atmosphere. The expanded gap may cause separation between the copper plate and the insulating core substrate.

Accordingly, it is an objective of the present invention to provide a circuit board that prevents separation of a metal plate caused by gap formation between an insulating core substrate and the metal plate. It is another objective of the invention to provide a method for manufacturing the circuit board.

### Means for Solving the Problems

In accordance with one aspect of the present disclosure, a circuit board for mounting an electronic component is provided that includes an insulating core substrate and a patterned metal plate. The metal plate is bonded to at least one side of the insulating core substrate. A gas-vent hole is formed in a laminated body configured by the insulating core substrate and the metal plate. The gas-vent hole is formed to release gas from between the insulating core substrate and the metal plate to a side open to the atmosphere through the gas-vent hole when the gas expands at the time of mounting the electronic component.

There may be cases where a gap is formed between an insulating core substrate and a metal plate when the metal plate is bonded to the insulating core substrate. The gas in the gap would expand when heated at the time of mounting an electronic component. However, in the above-described configuration, the gas escapes through the gas-vent hole. In other words, the gas in the gap is sent into the atmosphere through the gas-vent hole. As a result, the metal plate is prevented from being separated from the insulating core substrate by the gap between the insulating core substrate and the metal plate.

According to one form of the disclosure, the gas-vent hole includes a first through hole extending through both the insulating core substrate and the metal plate.

According to one form of the disclosure, the gas-vent hole is a groove formed in at least one of bonded surfaces of the insulating core substrate and the metal plate.

According to one form of the disclosure, a conductive pattern formed by the metal plate is bonded to each of opposite sides of the insulating core substrate. The circuit board further includes a conductive material that is adapted to fill the first through hole to electrically connect the conductive patterns to each other.

In this configuration, a plating process is unnecessary when the conductive patterns, which are configured by the metal plates bonded to the opposite sides of the insulating core substrate, are electrically connected to each other.

According to one form of the disclosure, the circuit board further includes a heat release member to which the laminated body is bonded.

In this configuration, the laminated body, which is formed by the insulating core substrate and the metal plate, is bonded to the heat release member. As a result, the heat generated by the electronic component is released from the heat release member.

According to one form of the disclosure, the circuit board further includes a second gas-vent hole formed in the heat release member. The second gas-vent hole is formed to release gas from between the heat release member and the laminated body to the side open to the atmosphere through the second gas-vent hole when the gas expands at the time of mounting the electronic component.

There may be cases where a gap is formed between the heat release member and the laminated body when the laminated body is bonded to the heat release member. The gas in the gap would expand when the gas is heated at the time of mounting an electronic component. However, in the above-described configuration, the gas escapes through the gas-vent hole formed in the heat release member. This prevents component separation after the heat is released.

According to one form of the disclosure, the insulating core substrate has a first side and a second side, and the metal plate is bonded to the first side. A component embedding insulating substrate is laminated on the second side with a spacer arranged in between. The electronic component is embedded between the component embedding insulating substrate and the spacer. The gas-vent hole includes a second through hole extending through the insulating core substrate. The circuit board further includes a conductive material that is adapted to fill the second through hole to electrically connect the electronic component and the conductive pattern to each other.

In this configuration, the electronic component is electrically connected to the conductive pattern configured by the metal plate by filling the third through hole, which extends through the insulating core substrate, with the conductive material. As a result, the circuit board is reduced in size.

According to one form of the disclosure, the metal plate is a copper plate.

In accordance with another aspect of the present invention, a method for manufacturing a circuit board is provided that includes: laminating an insulating core substrate and a metal plate together onto each other; pressing the insulating core substrate and the metal plate using a pressing member to bond the insulating core substrate to the metal plate and form a gas-vent hole; mounting an electronic component onto the metal plate; and allowing gas between the insulating core substrate and the metal plate to expand at the time of mounting the electronic component and to be released to a side open to the atmosphere through the gas-vent hole.

This method ensures release of the gas from between the insulating core substrate and the metal plate to the open atmospheric air side through the gas-vent hole when the gas expands at the time of mounting the electronic component. As a result, the metal plate is prevented from being separated by the gap between the insulating core substrate and the metal plate.

Other aspects and advantages of the discloser will become apparent from the following description, taken in conjunction with the accompanying drawings, illustrating by way of example the principles of the disclosure.

### BRIEF DESCRIPTION OF THE DRAWINGS

The features of the present disclosure that are believed to be novel are set forth with particularity in the appended claims. The disclosure, together with objects and advantages thereof, may best be understood by reference to the following description of the presently preferred embodiments together with the accompanying drawings in which:

FIG. 1 is a longitudinal cross-sectional view showing an electronic device according to a first embodiment of the present invention;

FIG. 2 is a longitudinal cross-sectional view illustrating a method for manufacturing the electronic device shown in FIG. 1;

FIG. 3 is a longitudinal cross-sectional view showing an electronic device according to a second embodiment of the present invention;

FIG. 4 is a longitudinal cross-sectional view illustrating a method for manufacturing the electronic device shown in FIG. 3;

FIG. 5 is a longitudinal cross-sectional view showing an electronic device according to a third embodiment of the present invention;

FIG. 6 is a longitudinal cross-sectional view illustrating a method for manufacturing the electronic device shown in FIG. 5; and

FIG. 7 is a longitudinal cross-sectional view showing an electronic device of a modified example.

### MODES FOR CARRYING OUT THE INVENTION

### First Embodiment

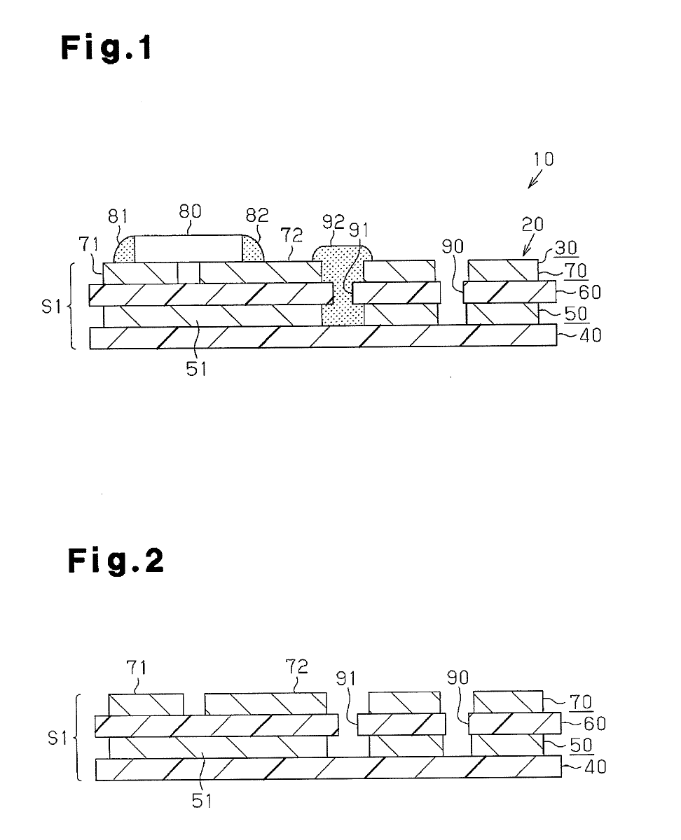

A first embodiment of the present invention will now be described with reference to FIGS. 1 and 2.

As shown in FIG. 1, an electronic device 10 has a circuit board 20, which has a wiring board 30. An electronic component 80, which serves as a surface mounted component, is mounted on the wiring board 30.

In the wiring board 30, a copper plate 50 serving as a first metal plate, an insulating core substrate 60, and a copper plate 70 serving as a second metal plate are sequentially laminated on an insulating core substrate 40. The copper plate 50 is patterned through punching in a desired shape to form a conductive pattern 51. Likewise, the copper plate 70 is patterned through punching in a predetermined shape to form conductive patterns 71, 72.

The patterned copper plate 50 is bonded to the upper side, or, in other words, one side, of the insulating core substrate 40. The insulating core substrate 60 is bonded to the upper side, or one side, of the copper plate 50. The patterned copper plate 70 is bonded to the upper side, or one side, of the insulating core substrate 60. The insulating core substrate 40, the copper plate 50, the insulating core substrate 60, and the copper plate 70 are bonded together through lamination pressing. In other words, as illustrated in FIG. 2, the insulating core substrate 40, an adhesive sheet (not shown), the copper plate 50, another adhesive sheet (not shown), the insulating core substrate 60, another adhesive sheet (not shown), and the copper plate 70 are sequentially laminated on a table (not shown) carrying the electronic device 10. The insulating core substrate 40, the corresponding adhesive sheet, the copper plate 50, the corresponding adhesive sheet, the insulating core substrate 60, the corresponding adhesive sheet, and the copper plate 70 are bonded together by lowering a pressing member onto the laminated components and pressing the components together. The up-and-down and left-and-right directions in the drawings are defined only for illustrative purposes and the electronic device 10 does not necessarily have to be oriented in the illustrated posture.

An electronic component 80 is mounted on the patterned copper plate 70. The electronic component 80 is bonded to the patterned copper plate 70 using solder bumps 81, 82. Specifically, the conductive pattern 71, which is a portion of the patterned copper plate 70, and the electronic component 80 are electrically connected to each other through soldering. The conductive pattern 72, which is another portion of the patterned copper plate 70, and the electronic component 80 are electrically connected to each other through soldering.

In the first embodiment, a thick copper substrate is employed as the wiring board 30 in the above-described manner.

A laminated body S1 is formed by the insulating core substrate 40, the copper plate 50, the insulating core substrate 60, and the copper plate 70. Through holes 90, 91 each serving as a gas-vent hole are formed in the laminated body S1 and extend through the copper plate 50, the insulating core substrate 60, and the copper plate 70. The through holes 90, 91 each serving as a first through hole function as gas-vent holes employed in a reflow soldering step. In other words, the through holes 90, 91 prevent expansion of the gap, or the void, between the insulating core substrate 40 and the copper plate 50, the gap, or the void, between the copper plate 50 and the insulating core substrate 60, and the gap, or the void, between the insulating core substrate 60 and the copper plate 70.

As has been described, the gas-vent holes of the first embodiment are the through holes 90, 91, which extend through the insulating core substrate 60 and the copper plates 50, 70.

A solder bump 92 serving as a conductive material fills the through hole 91, which extends through the copper plate 50, the insulating core substrate 60, and the copper plate 70. The solder bump 92 ensures conduction between the conductive pattern 51, which is a portion of the patterned copper plate 50, and the conductive pattern 72, which is a portion of the patterned copper plate 70.

Operation of the electronic device 10 will hereafter be described.

As illustrated in FIG. 2, the insulating core substrate 40, an adhesive sheet, the copper plate 50, another adhesive sheet, the insulating core substrate 60, another adhesive sheet, and the copper plate 70 are sequentially laminated at the time of lamination pressing in the manufacturing steps (in a lamination step). Subsequently, a pressing member is lowered onto and pressed against the laminated components at a high temperature to bond the insulating core substrate 40 to the copper plate 50, the copper plate 50 to the insulating core substrate 60, and the insulating core substrate 60 to the copper plate 70 and to form the through holes 90, 91 each serving as the gas-vent hole (a substrate forming step). In other words, the through holes 90, 91 are formed by bonding the insulating core substrate 40 to the copper plate 50, the copper plate 50 to the insulating core substrate 60, and the insulating core substrate 60 to the copper plate 70 at a high temperature. Bonding between the insulating core substrate 40 and the copper plate 50, bonding between the copper plate 50 and the insulating core substrate 60, and bonding between the insulating core substrate 60 and the copper plate 70 are accomplished by lowering the pressing member onto the insulating core substrate 40, the corresponding adhesive sheet, the copper plate 50, the corresponding adhesive sheet, the insulating core substrate 60, the corresponding adhesive sheet, and the copper plate 70 to press the laminated components.

At this stage, a gap is formed between the insulating core substrate 40 and the copper plate 50, between the copper plate 50 and the insulating core substrate 60, and between the insulating core substrate 60 and the copper plate 70. These gaps are caused by insufficient adhesion between the copper plates and the insulating core substrates.

Subsequently, in a step of mounting the electronic component 80, which is a surface mounted component, solder paste applied onto the copper plate 70 is heated to a high temperature in a reflow oven. For example, the solder paste is heated to approximately 250° C.

Such heating would cause expansion of the gas in the gap between the insulating core substrate 40 and the copper plate 50, the gas in the gap between the copper plate 50 and the insulating core substrate 60, and the gas in the gap between the insulating core substrate 60 and the copper plate 70. However, the gas in each gap escapes through the through holes 90, 91 each serving as the gas-vent hole (a gas releasing step). This prevents expansion of the gap between the insulating core substrate 40 and the copper plate 50, the gap between the copper plate 50 and the insulating core substrate 60, and the gap between the insulating core substrate 60 and the copper plate 70. As a result, separation of the copper plates 50, 70 is prevented, and improved adhesion performance is brought about between the insulating core substrate 40 and the copper plate 50, the copper plate 50 and the insulating core substrate 60, and the insulating core substrate 60 and the copper plate 70.

A solder bump 92 fills the through hole 91 in a soldering step. This ensures conduction between the conductive pattern 51 configured by the copper plate 50 and the conductive pattern 72 configured by the copper plate 70, which is conduction between layers.

The first embodiment has the advantages described below.

(1) The circuit board 20 is configured by bonding the patterned copper plates 50, 70 with the surfaces of the corresponding insulating core substrates 40, 60. In a broader sense, each of the patterned copper plates 50, 70 is bonded to at least one side of the corresponding one of the insulating core substrates 40, 60 and the electronic component 80 is mounted on this side. When the electronic component 80 is mounted, the gas between each insulating core substrate 40, 60 and the corresponding copper plate 50, 70 would expand in the laminated body S1 formed by the insulating core substrates 40, 60 and the copper plates 50, 70. To release the gas to the side open to the atmosphere, the through holes 90, 91 are employed. In other words, the first embodiment has a gas-vent structure for a state in which the insulating core substrates 40, 60 and the copper plates 50, 70 are pressed in the laminated state. That is, the first embodiment has the gas-vent structure for a state in which the laminated body S1 formed by the insulating core substrates 40, 60 and the copper plates 50, 70 is pressed.

Accordingly, when the insulating core substrates 40, 60 are bonded to the corresponding copper plates 50, 70, even though gaps are formed between the insulating core substrate 40 and the copper plate 50, between the copper plate 50 and the insulating core substrate 60, and between the insulating core substrate 60 and the copper plate 70, the following advantage is achieved. That is, even if the gaps are heated at the time of mounting the electronic component 80 and the gas in each of the gaps would expand, the gas thus escapes through the through holes 90, 91 to prevent separation of each copper plate 50, 70, which would be caused by the gap between the corresponding insulating core substrate 40, 60 and the copper plate 50, 70.

In other words, the thick copper substrate obtains the gas-vent structure by forming the through holes 90, 91 in the laminated body S1 formed by the copper plates 50, 70 and the insulating core substrates 40, 60. This prevents each copper plate 50, 60 from separating from the corresponding insulating core substrate 40, 60 at the time of reflow soldering. As a result, improved adhesion performance is ensured.

(2) The conductive patterns 51, 72, which are the patterned copper plates 50, 70 bonded to the opposite sides of the insulating core substrates 60, are electrically connected to each other by filling the through hole 91 with the solder bump 92 serving as the conductive material. This makes it unnecessary to perform a plating process to electrically connect the conductive patterns 51, 72, which are the patterned copper plates 50, 70 bonded to the opposite sides of the insulating core substrate 60, to each other.

(3) The method for manufacturing the circuit board includes the lamination step, the substrate forming step, the mounting step, and the gas releasing step. In the lamination step, the insulating core substrates 40, 60 and the copper plates 50, 70 are laminated together. In the substrate forming step, the pressing member is pressed against the insulating core substrates 40, 60 and the metal plates 50, 70. This bonds the insulating core substrates 40, 60 to the corresponding copper plates 50, 70 and thus forms the through holes 90, 91 each serving as the gas-vent hole. In the mounting step, the electronic component 80 is mounted on the copper plate 70. In the gas releasing step, when the gas between each insulating core substrate 40, 60 and the corresponding copper plate 50, 70 expands at the time of mounting the electronic component 80, the gas escapes through the through holes 90, 91 each serving as the gas-vent hole to the side open to the atmosphere. As a result, the copper plates 50, 70 are prevented from being separated from the corresponding insulating core substrates 40, 60 by the gaps between the insulating core substrates 40, 60 and the copper plates 50, 70.

### Second Embodiment

A second embodiment of the present invention will now be described mainly on the difference between the first embodiment and the second embodiment.

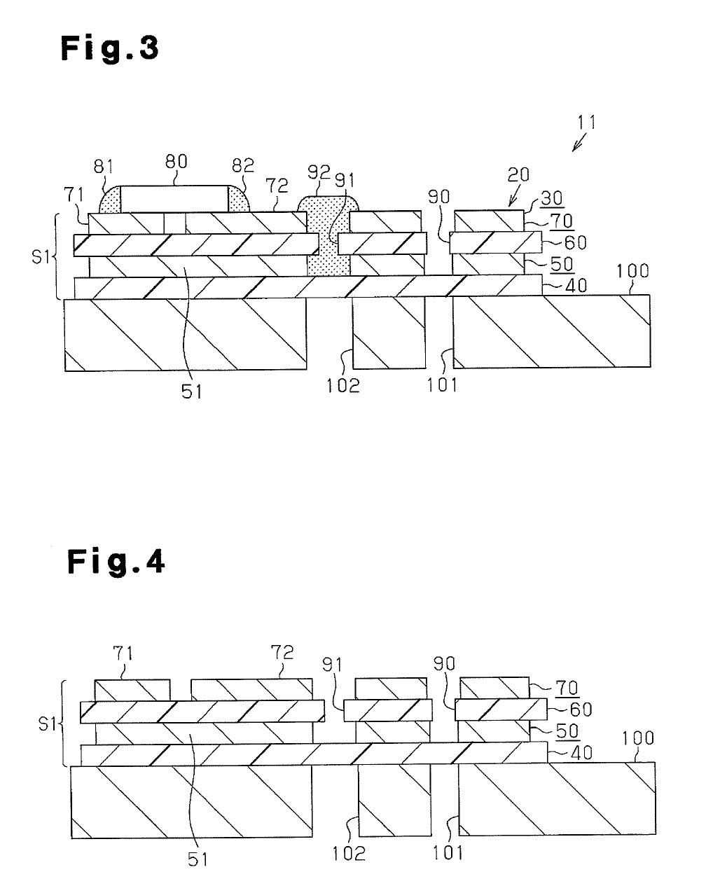

The second embodiment is configured differently from the configuration of FIG. 1, as illustrated in FIG. 3. With reference to FIG. 3, an electronic device 11 has a heat release plate 100 formed of aluminum and a circuit board 20 mounted on the heat release plate 100. The heat produced by the electronic component 80 escapes from the heat release plate 100 through the laminated body S1, which is included in the circuit board 20.

The insulating core substrate 40 is arranged on the upper side of the heat release plate 100. The heat release plate 100, the insulating core substrate 40, the copper plate 50, the insulating core substrate 60, and the copper plate 70 are bonded together through lamination pressing. That is, as illustrated in FIG. 4, the heat release plate 100, a first adhesive sheet (not shown), the insulating core substrate 40, a second adhesive sheet (not shown), the copper plate 50, a third adhesive sheet (not shown), the insulating core substrate 60, an adhesive sheet, and the copper plate 70 are laminated sequentially on the table (not shown) carrying the electronic device 11. A pressing member is lowered onto and pressed against the heat release plate 100, the corresponding adhesive sheet, the insulating core substrate 40, the corresponding adhesive sheet, the copper plate 50, the corresponding adhesive sheet, the insulating core substrate 60, the corresponding adhesive sheet, and the copper plate 70, thus bonding the laminated components together.

Through holes 101, 102 each serving as a second gas-vent hole are formed in the heat release plate 100 serving as a heat release member, extending through the heat release plate 100.

Operation of the electronic device 11, which has the through holes corresponding to the through holes 101, 102 formed in the heat release plate 100 as has been described, will hereafter be described.

At the time of lamination pressing in the manufacturing steps, the heat release plate 100, the corresponding adhesive sheet, the insulating core substrate 40, the corresponding adhesive sheet, the copper plate 50, the corresponding adhesive sheet, the insulating core substrate 60, the corresponding adhesive sheet, and the copper plate 70 are laminated sequentially as illustrated in FIG. 4. A pressing member is lowered onto and pressed against the laminated components at a high temperature to bond the heat release plate 100 to the insulating core substrate 40, the insulating core substrate 40 to the copper plate 50, the copper plate 50 to the insulating core substrate 60, and the insulating core substrate 60 to the copper plate 70. The through holes 101, 102 serving as the gas-vent holes are formed. The through holes 90, 91 are formed by bonding the heat release plate 100 to the insulating core substrate 40, the insulating core substrate 40 to the copper plate 50, the copper plate 50 to the insulating core substrate 60, and the insulating core substrate 60 to the copper plate 70 at a high temperature.

At this stage, gaps as voids are formed between the heat release plate 100 and the insulating core substrate 40, between the insulating core substrate 40 and the copper plate 50, between the copper plate 50 and the insulating core substrate 60, and between the insulating core substrate 60 and the copper plate 70.

Subsequently, in a step of mounting the electronic component 80 serving as the surface mounted component, the solder paste applied on the copper plate 70 is heated to a high temperature in a reflow oven.

Such heating would expand the gas in the gap between the heat release plate 100 and the insulating core substrate 40. However, the gas escapes through the through holes 101, 102 serving as the gas-vent holes. Similarly, when the gas in the gap between the insulating core substrate 40 and the copper plate 50, the gas in the gap between the copper plate 50 and the insulating core substrate 60, and the gas in the gap between the insulating core substrate 60 and the copper plate 70 would expand, the gas escapes through the through holes 90, 91 serving as the gas-vent holes.

By releasing the gas from the gaps in the electronic device 11 through the gas-vent holes, the gap between the heat release plate 100 and the insulating core substrate 40, the gap between the insulating core substrate 40 and the copper plate 50, the gap between the copper plate 50 and the insulating core substrate 60, and the gap between the insulating core substrate 60 and the copper plate 70 are prevented from expanding. This prevents separation of the copper plates 50, 70 and the heat release plate 100 from the corresponding insulating core substrates 40, 60. In other words, improved adhesion performance is ensured between the heat release plate 100 and the insulating core substrate 40, the insulating core substrate 40 and the copper plate 50, the copper plate 50 and the insulating core substrate 60, and the insulating core substrate 60 and the copper plate 70.

This prevents expansion of a gap formed through insufficient adhesion caused by, for example, insufficient pressing in the lamination pressing.

The second embodiment has the advantages described below.

(4) The laminated body S1 configured by the insulating core substrates 40, 60 and the copper plates 50, 70 is bonded to the heat release plate 100 serving as the heat release member. As a result, when the electronic component 80 produces heat, the heat is released from the heat release plate 100.

(5) The through holes 101, 102 are formed in the heat release plate 100 as the gas-vent holes for allowing the gas between the heat release plate 100 serving as the heat release member and the laminated body S1 to escape to the side open to atmosphere when the gas is expanded at the time of mounting the electronic component 80. As a result, if gap is formed between the heat release plate 100 and the laminated body S1 at the time of bonding the laminated body S1 with the heat release plate 100 and the gas in the gap is heated to expand at the time of mounting the electronic component 80 on the laminated body S1, the gas escapes through the through holes 101, 102 formed in the heat release plate 100. This prevents separation of the heat release plate 100 from the laminated body S1 and improves the adhesion performance between the heat release plate 100 and the laminated body S1.

### Third Embodiment

A third embodiment of the present invention will hereafter be described mainly on the difference between the first embodiment and the third embodiment.

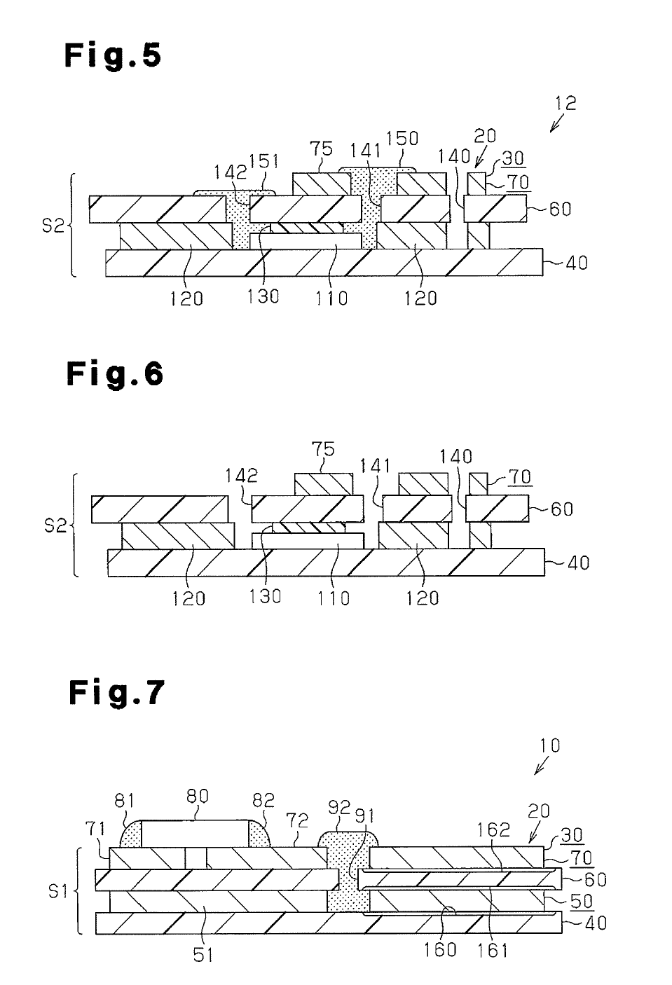

The third embodiment is configured differently from the configuration of FIG. 1, as illustrated in FIG. 5. With reference to FIG. 5, an electronic device 12 has an electronic component 110 mounted and incorporated between the insulating core substrate 40 and the insulating core substrate 60.

A spacer 120 having a thickness greater than the thickness of the electronic component 110 is arranged between the insulating core substrate 40 and the insulating core substrate 60 at a position around the electronic component 110. A copper pattern may be employed as the spacer 120. A thin plate material 130, which serves as another spacer, is arranged between the upper side of the electronic component 110 and the lower side of the insulating core substrate 60. The thin plate material 130 is bonded to the lower side of the insulating core substrate 60. The electronic component 110 is embedded between the insulating core substrate 40 serving as a component embedding insulating substrate and the thin plate material 130. The thin plate material 130 is a component for ensuring electric insulation between the electronic component 110 and the electrodes at the left and right sides and may be, for example, an adhesive.

The electronic component 110 and the spacer 120 are bonded to the upper side of the insulating core substrate 40. The insulating core substrate 60 is bonded to the upper side of the spacer 120. The insulating core substrate 40, the spacer 120, the electronic component 110, the thin plate material 130, the insulating core substrate 60, and the copper plate 70 are bonded together through lamination pressing. In other words, as illustrated in FIG. 6, the insulating core substrate 40, an adhesive sheet, the spacer 120, another adhesive sheet, the insulating core substrate 60, another adhesive sheet, and the copper plate 70 are laminated sequentially on a table. A pressing member is then lowered onto and pressed against the laminated components to bond the components together. In other words, with reference to FIG. 6, the insulating core substrate 40, an adhesive sheet, the electronic component 110, the thin plate material 130, another adhesive sheet, the insulating core substrate 60, another adhesive sheet, and the copper plate 70 are laminated sequentially on a table. A pressing member is then lowered onto and pressed against the laminated components to bond the components together.

Second through holes 140, 141 are formed in a laminated body S2 configured by the insulating core substrate 40, the spacer 120, the insulating core substrate 60, and the copper plate 70 and serve as gas-vent holes extending through the spacer 120, the insulating core substrate 60, and the copper plate 70. The through hole 141 is filled with a solder bump 150 serving as a conductive material. The solder bump 150 ensures conduction between a first electrode of the electronic component 110 and a conductive pattern 75 configured by the copper plate 70.

A through hole 142 is formed in the laminated body S2 configured by the insulating core substrate 40, the spacer 120, the insulating core substrate 60, and the copper plate 70, extending through the spacer 120 and the insulating core substrate 60. The through hole 142 is filled with a solder bump 151 serving as a conductive material. The solder bump 151 extends and exposes a second electrode of the electronic component 110 on the upper side of the insulating core substrate 60. As has been described, in the configuration having the electronic component 110 incorporated in the substrate, or, in other words, arranged between the insulating core substrate 40 and the insulating core substrate 60, soldering through the through holes 141, 142 ensures conduction in the electronic component 110.

Operation of the electronic device 12, which is configured in the above-described manner, will hereafter be described.

At the time of lamination pressing in the manufacturing steps, the insulating core substrate 40, an adhesive sheet, the spacer 120, another adhesive sheet, the insulating core substrate 60, another adhesive sheet, and the copper plate 70 are laminated sequentially as illustrated in FIG. 6. Alternatively, the insulating core substrate 40, an adhesive sheet, the electronic component 110, the thin plate material 130, another adhesive sheet, the insulating core substrate 60, another adhesive sheet, and the copper plate 70 are laminated sequentially. A pressing member is then lowered onto and pressed against the laminated components to bond the insulating core substrate 40 to the spacer 120, the spacer 120 to the insulating core substrate 60, and the insulating core substrate 60 to the copper plate 70.

At this stage, gaps are formed as voids between the insulating core substrate 40 and the spacer 120, between the spacer 120 and the insulating core substrate 60, and between the insulating core substrate 60 and the copper plate 70.

Subsequently, in a step of electrically connecting the electronic component 110, the applied solder paste is heated to a high temperature in a reflow oven.

Such heating would expand the gas in the gap between the insulating core substrate 40 and the spacer 120, the gas in the gap between the spacer 120 and the insulating core substrate 60, and the gas in the gap between the insulating core substrate 60 and the copper plate 70. However, the gas escapes through the through holes 140, 141 serving as the gas-vent holes. This prevents expansion of the gaps and thus separation of the components. Also, improved adhesion performance is ensured between the insulating core substrate 40 and the spacer 120, the spacer 120 and the insulating core substrate 60, and the insulating core substrate 60 and the copper plate 70.

The third embodiment has the advantage described below.

(6) The patterned copper plate 70 is bonded to a first side, which is, for example, the upper side, of the insulating core substrate 60. The insulating core substrate 40 serving as the component embedding insulating substrate is formed on a second side, which is, for example, the lower side, of the insulating core substrate 60 with the spacer 120 arranged between the insulating core substrate 40 and the insulating core substrate 60. The electronic component 110 is embedded between the insulating core substrate 40 and the insulating core substrate 60. The through hole 141, which extends through the insulating core substrate 60, functions as a gas-vent hole. The through hole 141 is filled with the solder bump 150 serving as the conductive material, which electrically connects the electronic component 110 to the conductive pattern 75 configured by the copper plate 70. That is, electrical connection between the electronic component 110 and the conductive pattern 75, which is configured by the copper plate 70, is accomplished by filling the through hole 141, which extends through the insulating core substrate 60, with the solder bump 150, or the conductive material. This configuration reduces the size of the circuit board.

The present invention is not restricted to the illustrated embodiments but may be embodied in the forms described below.

As shown in FIG. 3, the circuit board 20 is deployed only on one side, which is the upper side, of the heat release plate 100. However, the invention may be embodied with the circuit boards deployed on the opposite sides, which are the upper side and the lower side, of the heat release plate 100.

The gas-vent through holes, which include the through holes 90, 91 illustrated in FIG. 1, for example, may be replaced by grooves 160, 161, 162. Specifically, a recessed groove 160 may be formed in the upper side of the insulating core substrate 40 to release gas through the recessed groove 160. Also, a recessed groove 161 may be formed in the lower side of the insulating core substrate 60 to release gas from the recessed groove 161. Further, a recessed groove 162 may be formed in the upper side of the insulating core substrate 60 to release gas from the recessed groove 162.

In other words, in an embodiment having the laminated body S1 formed by the insulating core substrates 40, 60 and the copper plates 50, 70, each one of the grooves 160, 161, 162 serving as a gas-vent hole may be formed in a bonding surface between the corresponding one of the insulating core substrates 40, 60 and the associated one of the copper plates 50, 70. Specifically, gas communication is ensured between the bonding surface between each insulating core substrate 40, 60 and the corresponding copper plate 50, 70 and the gap corresponding to the open atmospheric air side. Accordingly, the gas-vent holes may be formed by the grooves 160, 161, 162, which are formed in the corresponding bonding surfaces between the insulating core substrates 40, 60 and the copper plates 50, 70.

The grooves 160, 161, 162 may be formed in the corresponding copper plates 50, 70 instead of the insulating core substrates 40, 60. Alternatively, the grooves 160, 161, 162 may be arranged in both the insulating core substrates 40, 60 and the copper plates 50, 70.

Although the copper plates 50, 70 are employed as the metal plates, the invention may be embodied with any other suitable metal plates, such as aluminum plates, as the metal plates.

The copper plates are patterned through punching before being bonded to the corresponding insulating core substrates. However, in an alternative configuration, a non-patterned thin copper plate may be bonded to an insulating core substrate and then patterned through etching.

### DESCRIPTION OF THE REFERENCE NUMERALS

10 . . . electronic device, 11 . . . electronic device, 12 . . . electronic device, 20 . . . circuit board, 30 . . . wiring board, 40 . . . insulating core substrate, 50 . . . copper plate, 60 . . . insulating core substrate, 70 . . . copper plate, 80 . . . electronic component, 90 . . . through hole, 91 . . . through hole, 92 . . . solder bump, 100 . . . heat release plate, 101 . . . through hole, 102 . . . through hole, 110 . . . electronic component, 120 . . . spacer, 140 . . . through hole, 141 . . . through hole, 160 . . . groove, 161 . . . groove, 162 . . . groove, S1 . . . laminated body, S2 . . . laminated body

1. A circuit board for mounting an electronic component, the circuit board comprising an insulating core substrate and a patterned metal plate, wherein
the metal plate is bonded to at least one side of the insulating core substrate,
a gas-vent hole is formed in a laminated body configured by the insulating core substrate and the metal plate, and
the gas-vent hole is formed to release gas from between the insulating core substrate and the metal plate to a side open to the atmosphere through the gas-vent hole when the gas expands at the time of mounting the electronic component.

2. The circuit board according to claim 1, wherein the gas-vent hole includes a first through hole extending through both the insulating core substrate and the metal plate.

3. The circuit board according to claim 1, wherein the gas-vent hole is a groove formed in at least one of bonded surfaces of the insulating core substrate and the metal plate.

4. The circuit board according to claim 2, wherein
a conductive pattern formed by the metal plate is bonded to each of opposite sides of the insulating core substrate, and
the circuit board further includes a conductive material that is adapted to fill the first through hole to electrically connect the conductive patterns to each other.

5. The circuit board according to claim 1, wherein the circuit board further includes a heat release member to which the laminated body is bonded.

6. The circuit board according to claim 5, wherein
the circuit board further includes a second gas-vent hole formed in the heat release member, and
the second gas-vent hole is formed to release gas from between the heat release member and the laminated body to the side open to the atmosphere through the second gas-vent hole when the gas expands at the time of mounting the electronic component.

7. The circuit board according to claim 1, wherein
the insulating core substrate has a first side and a second side,
the metal plate is bonded to the first side,
a component embedding insulating substrate is laminated on the second side with a spacer arranged in between,
the electronic component is embedded between the component embedding insulating substrate and the spacer,
the gas-vent hole includes a second through hole extending through the insulating core substrate, and
the circuit board further includes a conductive material that is adapted to fill the second through hole to electrically connect the electronic component and the conductive pattern to each other.

8. The circuit board according to any one of claim 1, wherein the metal plate is a copper plate.

9. A method for manufacturing a circuit board comprising:
laminating an insulating core substrate and a metal plate together onto each other;
pressing the insulating core substrate and the metal plate using a pressing member to bond the insulating core substrate to the metal plate and form a gas-vent hole;
mounting an electronic component onto the metal plate; and
allowing gas between the insulating core substrate and the metal plate to expand at the time of mounting the electronic component and to be released to a side open to the atmosphere through the gas-vent hole.
